(19) United States
(12) Patent Application Publication
(10) Pub. No.: US 2025/0259949 A1
(43) Pub. Date: Aug. 14, 2025

(54) SEMICONDUCTOR DEVICE AND MANUFACTURING METHOD THEREOF

(71) Applicant: NANYA TECHNOLOGY CORPORATION, New Taipei city (TW)

(72) Inventor: Sheng-Fu HUANG, New Taipei City (TW)

(21) Appl. No.: 18/438,499

(22) Filed: Feb. 11, 2024

(51) Int. Cl. H01L 23/00

(52) U.S. Cl. CPC H01L 24/02; H01L 24/03; H01L 24/05; H01L 24/08; H01L 24/80; H01L 2224/0213; H01L 2224/0215; H01L 2224/03452; H01L 2224/05647; H01L 2224/05684; H01L 2224/08145; H01L 2224/80007; H01L 2224/80143; H01L 2924/0132; H01L 2924/05381

(57) ABSTRACT

In accordance with an aspect of the present disclosure, a semiconductor device is provided. The semiconductor device includes a first semiconductor wafer and a second semiconductor wafer, wherein the second semiconductor wafer disposed on the first semiconductor wafer. The first semiconductor wafer includes a first substrate, a first metallization layer, a first dielectric layer, a first magnetic structure, and a first metal pad. The second semiconductor wafer includes a second substrate, a second metallization layer, a second dielectric layer, a second magnetic structure, and a second metal pad. The first magnetic structure is aligned with and in direct contact with the second magnetic structure, and a top surface of the first dielectric layer is in direct contact with a top surface of the second dielectric layer.

### BACKGROUND

### Field of Invention

The present invention relates to a semiconductor device and manufacturing method thereof. More particularly, the present invention relates to hybrid bonding process using magnetic material.

### Description of Related Art

Generally, hybrid bonding process includes bonding metal and dielectric film. Hybrid bonding usually includes a thermal process and a pressure process, which may shift the thermal budget and may also cause the dielectric film crack.

Accordingly, the present disclosure provides a semiconductor device and manufacturing method thereof, wherein the hybrid bonding process does not include thermal process and/or pressure process.

### SUMMARY

In accordance with an aspect of the present disclosure, a semiconductor device is provided. The semiconductor device includes a first semiconductor wafer and a second semiconductor wafer, wherein the second semiconductor wafer disposed on the first semiconductor wafer. The first semiconductor wafer includes a first substrate, a first metallization layer disposed on a top surface of the first substrate, a first dielectric layer disposed on the first metallization layer, a first magnetic structure embedded in the first dielectric layer, and a first metal pad embedded in the first dielectric layer, wherein the first metal pad connect with a first interconnect structure in the first metallization layer. The second semiconductor wafer includes a second substrate, a second metallization layer disposed on a top surface of the second substrate, a second dielectric layer disposed on the second metallization layer, a second magnetic structure embedded in the second dielectric layer, and a second metal pad embedded in the second dielectric layer, wherein the second metal pad connect with a second interconnect structure in the first metallization layer. The first magnetic structure is aligned with and in direct contact with the second magnetic structure, and a top surface of the first dielectric layer is in direct contact with a top surface of the second dielectric layer.

According to some embodiments of the present disclosure, wherein the first magnetic structure and the second magnetic structure comprise a material selected from the group consisting of iron oxides, iron-cobalt alloy, iron-nickel alloy, iron-aluminum alloy or combinations thereof.

According to some embodiments of the present disclosure, wherein the first magnetic structure and the second magnetic structure have opposite polarities.

According to some embodiments of the present disclosure, further including: a package structure covering the first semiconductor wafer and the second semiconductor wafer.

According to some embodiments of the present disclosure, wherein the second semiconductor wafer includes a conductive via extending from a bottom surface of the second substrate to the second interconnect structure of the second metallization layer.

According to some embodiments of the present disclosure, wherein the first metal pad is aligned with and in direct contact with the second metal pad.

In accordance with an aspect of the present disclosure, a manufacturing method of a semiconductor device is provided. The method include following steps. A first semiconductor wafer is provided, wherein the first semiconductor wafer comprises a first substrate and a first metallization layer disposed on a top surface of the first substrate. A first magnetic layer is formed on a top surface of the first metallization layer. The first magnetic layer is patterned to form a first magnetic structure. A first dielectric layer is formed on the first magnetic structure, wherein the first magnetic structure is embedded in the first dielectric layer. A first metal pad is formed in the first dielectric layer. A planarization process is performed to expose a top surface of the first magnetic structure. A magnetization process is performed on the first magnetic structure.

According to some embodiments of the present disclosure, wherein patterning the first magnetic layer includes: forming a hard mask layer on the first magnetic layer. A photoresist layer is formed on the hard mask layer. The photoresist layer and the hard mask layer are patterned to define a pattern of the first magnetic structure.

According to some embodiments of the present disclosure, further including: stripping the photoresist layer before forming the second dielectric layer on the second magnetic structure.

According to some embodiments of the present disclosure, further including: performing a planarization process on the first dielectric layer before forming the first metal pad.

According to some embodiments of the present disclosure, wherein forming the first metal pad including: removing a portion of the first dielectric layer to form a trace. And a conductive material is filled in the trace to form the first metal pad.

According to some embodiments of the present disclosure, further includes following steps. A second semiconductor wafer is provided, wherein the second semiconductor wafer comprises a second substrate and a second metallization layer disposed on a top surface of the second substrate. A second magnetic layer is formed on a top surface of the second metallization layer. The second magnetic layer is patterned to form a second magnetic structure. A second dielectric layer is formed on the second magnetic structure, wherein the second magnetic structure is embedded in the second dielectric layer. A second metal pad is formed in the second dielectric layer. A planarization process is performed to expose a top surface of the second magnetic structure. A magnetization process is performed on the second magnetic structure.

According to some embodiments of the present disclosure, wherein the first magnetic structure and the second magnetic structure have opposite polarities.

According to some embodiments of the present disclosure, wherein before providing the second semiconductor wafer includes: forming a conductive via in the second metallization layer, wherein the conductive via extends from a bottom surface of the second substrate to a interconnect structure of the second metallization layer.

According to some embodiments of the present disclosure, further including: aligning the first magnetic structure and the second magnetic structure to bond the first semiconductor wafer and the second semiconductor wafer, wherein the first magnetic structure and the second magnetic structure direct contact with each other.

According to some embodiments of the present disclosure, wherein after bonding the first semiconductor wafer and the second semiconductor wafer includes: forming a package structure on the second semiconductor wafer, such that the package structure covers the first semiconductor wafer and the second semiconductor wafer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-10 are cross-sectional view schematic diagrams of various intermediate stages in the formation of a first semiconductor wafer, in accordance with some embodiments;

FIG. 11 is a cross-sectional view schematic diagram of a second semiconductor wafer, in accordance with some embodiments; and

FIG. 12 is a cross-sectional view schematic diagram of a semiconductor device, in accordance with some embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

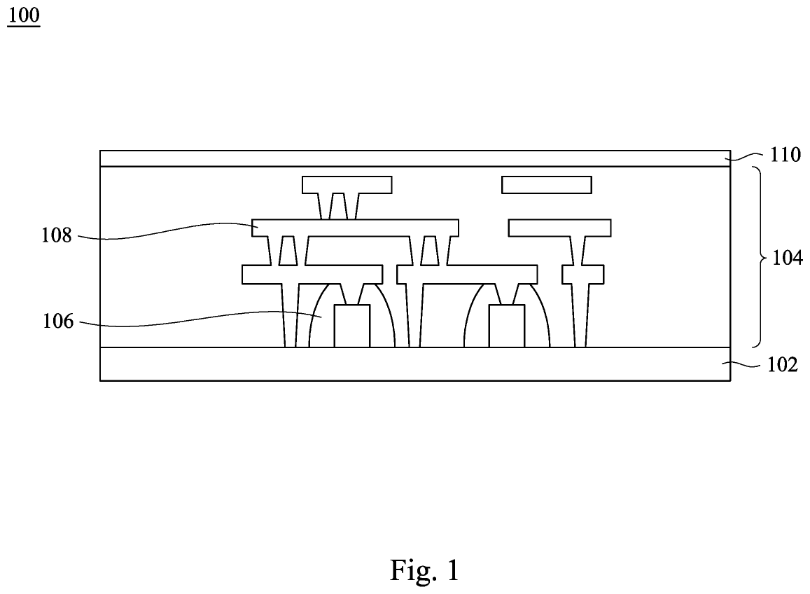

FIG. 1 is a cross-sectional view schematic diagram of the first semiconductor wafer 100, in accordance with some embodiments. The first semiconductor wafer 100 includes a first substrate 102 and a first metallization layer 104, wherein the first metallization layer 104 is disposed on a top surface of the first substrate 102. The first metallization layer 104 includes transistor 106 and first interconnect structure 108.

In some embodiments, the first substrate 102 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the first substrate 102 can be doped (eg, containing p-type or n-type dopants) or undoped. In some embodiments, the semiconductor material of the first substrate 102 may include silicon, germanium, compound semiconductors (including silicon carbide, gallium arsenide, gallium phosphide, indium phosphide, indium arsenide, and/or indium antimonide), alloy semiconductors or a combination thereof. The first substrate 102 can also be formed of other materials, such as sapphire, indium tin oxide, and the like.

In some embodiments, the first metallization layer 104 may include one or more active device such as transistor 106. In some embodiments, the first interconnect structure 108 is embedded in the first metallization layer 104. The first interconnect structure 108 may include conductive material such as metal, metal alloy, metal nitride, or the like. For example, first interconnect structure 108 may include copper, tungsten, or other suitable conductive material.

Referring to FIG. 1, a first magnetic layer 110 is formed on a top surface of the first metallization layer 104. In some embodiments, the first magnetic layer 110 is formed by ferroelectric deposition process. In some embodiments, the first magnetic layer 110 may include iron oxide, such as Fe₃O₄. In some embodiments, the first magnetic layer 110 may include iron-cobalt alloy, iron-nickel alloy, iron-aluminum alloy or combinations thereof.

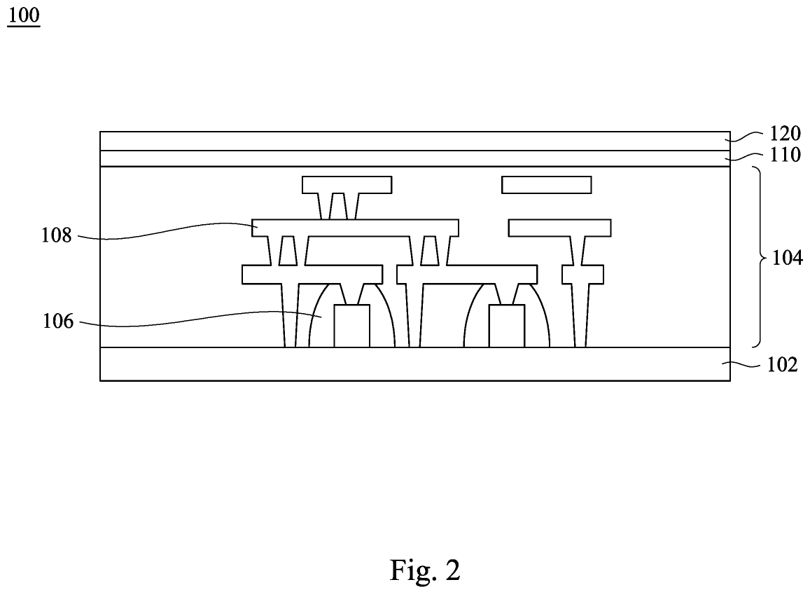

Referring to FIG. 2, a hard mask layer 120 is formed on the first magnetic layer 110. The hard mask layer 120 include a dielectric material, such as tetraethylorthosilicate (TEOS), a low-k dielectric material, doped silicon oxide (e.g., borophosphosilicate glass (BPSG), fused silica glass (FSG), phosphosilicate glass (PSG), boron doped silicon glass (BSG), etc.), and/or other suitable dielectric materials. In some embodiments, the hard mask layer 120 may be formed using a suitable deposition process, such as chemical vapor deposition (CVD), plasma enhanced chemical vapor deposition (PECVD), atomic layer deposition (ALD), or the like.

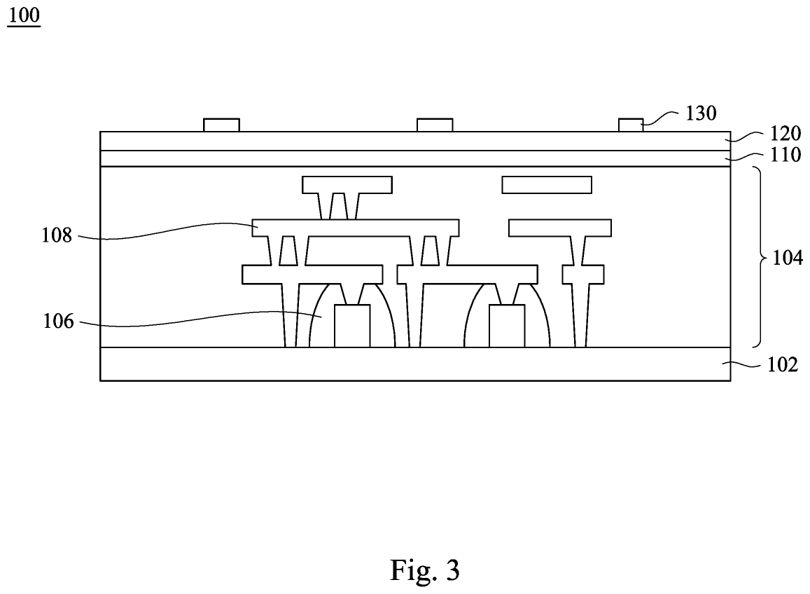

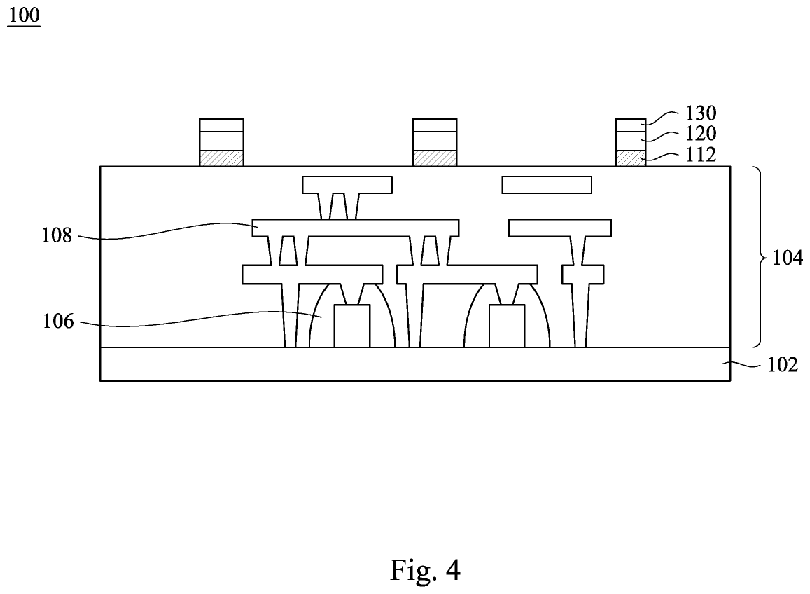

Referring to FIG. 3, a photoresist layer 130 is formed on the hard mask layer 120. In some embodiments, the photoresist layer 130 may include carbon and hydrogen. In some embodiments, the photoresist layer 130 may be formed by any suitable deposition process such as chemical vapor deposition (CVD), atomic layer deposition (ALD), or physical vapor deposition (PVD). Then the photoresist layer 130 is patterned to protect and define the pattern of the first magnetic structure 142, which may be discussed in FIG. 4. The photoresist layer 130 can be patterned by a suitable method, such as photolithography patterning and etching.

Referring to FIG. 4, a portion of the first magnetic layer 110 is removed to form a first magnetic structure 112. In some embodiments, a portion of the hard mask layer 120 and a portion of the first magnetic layer 110 are removed using a suitable dry etching process, such as reactive ion etching (RIE) process, or other suitable anisotropic etching processes. In other words, the portion of the first magnetic layer 110 under the photoresist layer 130 is retained to form the first magnetic structure 112.

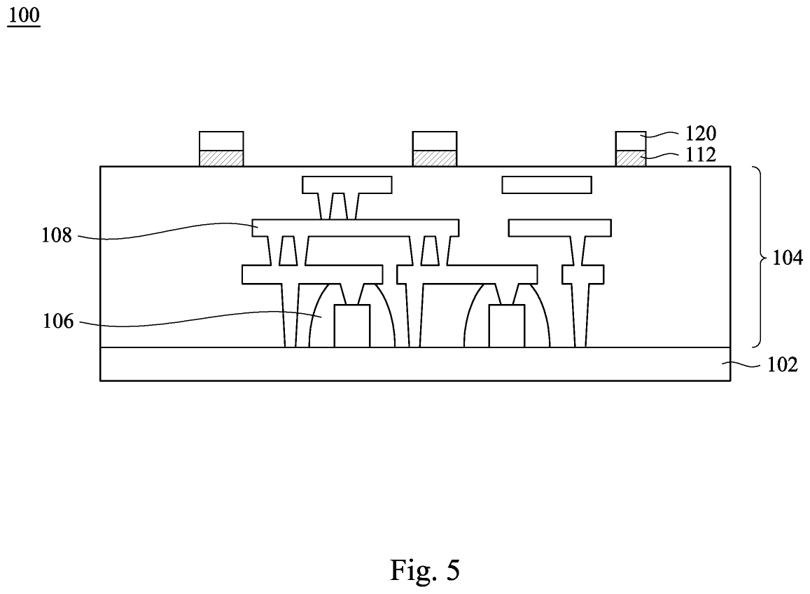

Referring to FIG. 5, the photoresist layer 130 is removed. In some embodiments, the photoresist layer 130 is removed using a suitable stripping process. After the photoresist layer 130 is removed, the hard mask layer 120 is exposed.

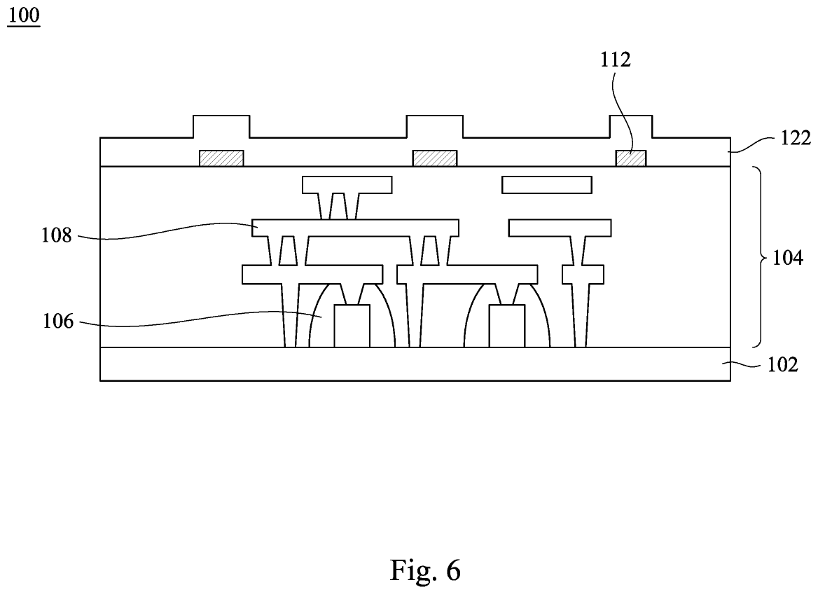

Referring to FIG. 6, a first dielectric layer 122 is formed on the first magnetic structure 122, wherein the first magnetic structure 112 is embedded in the first dielectric layer 122. The first dielectric layer 122 include a dielectric material, such as tetraethylorthosilicate (TEOS), a low-k dielectric material, doped silicon oxide (e.g., borophosphosilicate glass (BPSG), fused silica glass (FSG), phosphosilicate glass (PSG), boron doped silicon glass (BSG), etc.), and/or other suitable dielectric materials. In some embodiments, the first dielectric layer 122 may be formed using a suitable deposition process, such as chemical vapor deposition (CVD), plasma enhanced chemical vapor deposition (PECVD), atomic layer deposition (ALD), or the like.

In some embodiments, the first dielectric layer 122 and the hard mask layer 120 may include same material. In FIG. 6, the first dielectric layer 122 and the hard mask layer 120 include same material. In some embodiments, the first dielectric layer 122 and the hard mask layer 120 may include the different materials. In some embodiment, the hard mask layer 120 is removed before forming the first dielectric layer 122.

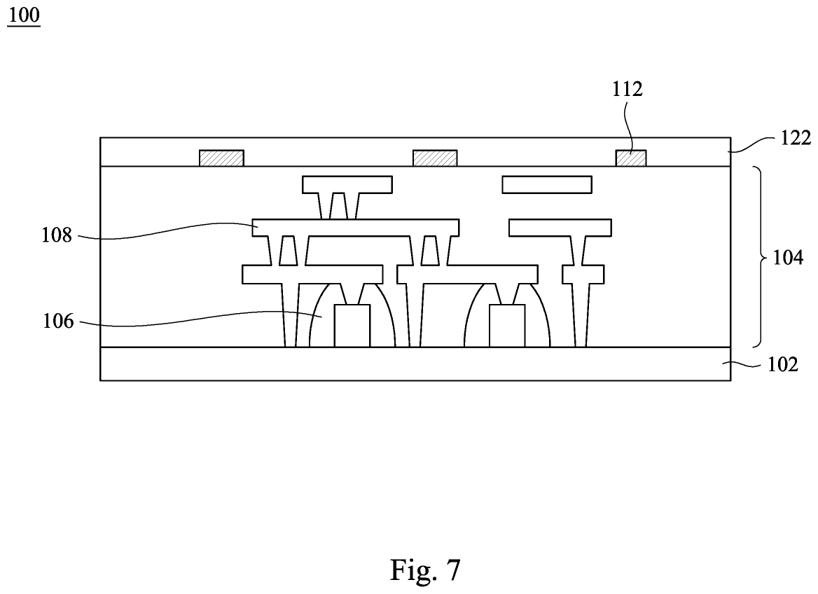

Referring to FIG. 7, a planarization process is performed on the first dielectric layer 122. In some embodiments, the planarization process is a chemical mechanical planarization (CMP) process.

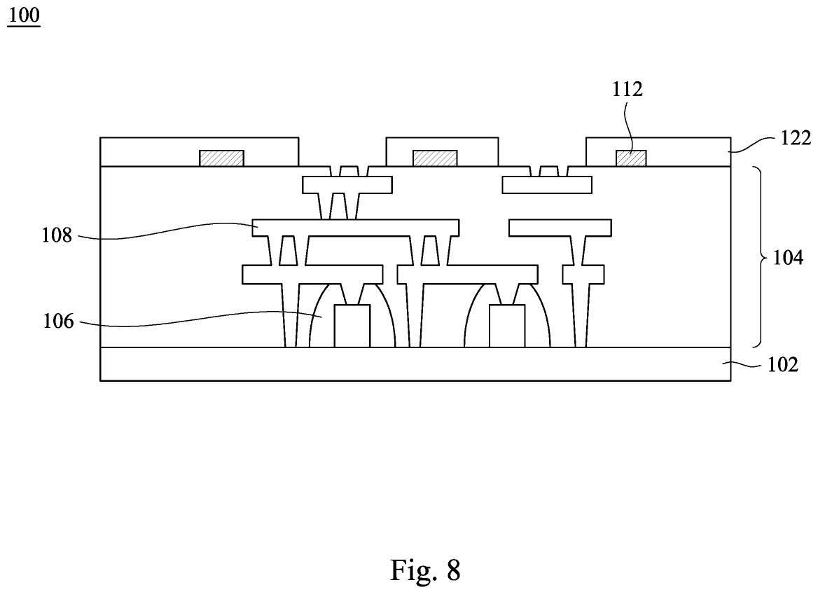

Referring to FIG. 8, a portion of the first dielectric layer 122 is removed to form a trace T. The trace T exposes a portion of the top surface of the first interconnect structure 108. The portion of the first dielectric layer 122 is removed using a suitable dry etching process, such as reactive ion etching (RIE) process, or other suitable anisotropic etching processes.

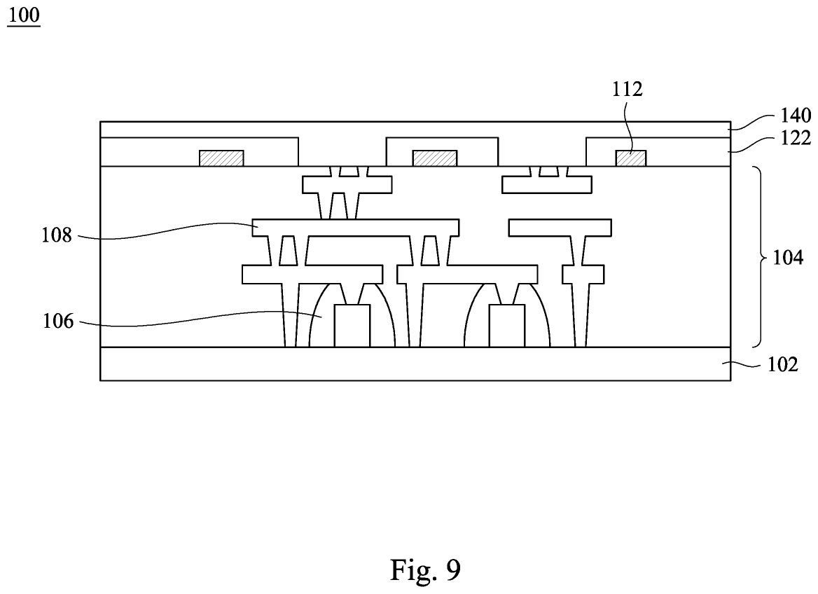

Referring to FIG. 9, a first metal pad 140 is formed by filling a conductive material in the trace T. The first metal pad 140 may cover the top surface of the first dielectric layer. The first metal pad 140 may include conductive material such as metal, metal alloy, metal nitride, or the like. For example, first metal pad 140 may include copper, tungsten, or other suitable conductive material. In some embodiments, the first dielectric layer 122 may be formed using a suitable deposition process, such as chemical vapor deposition (CVD), plasma enhanced chemical vapor deposition (PECVD), atomic layer deposition (ALD), or the like.

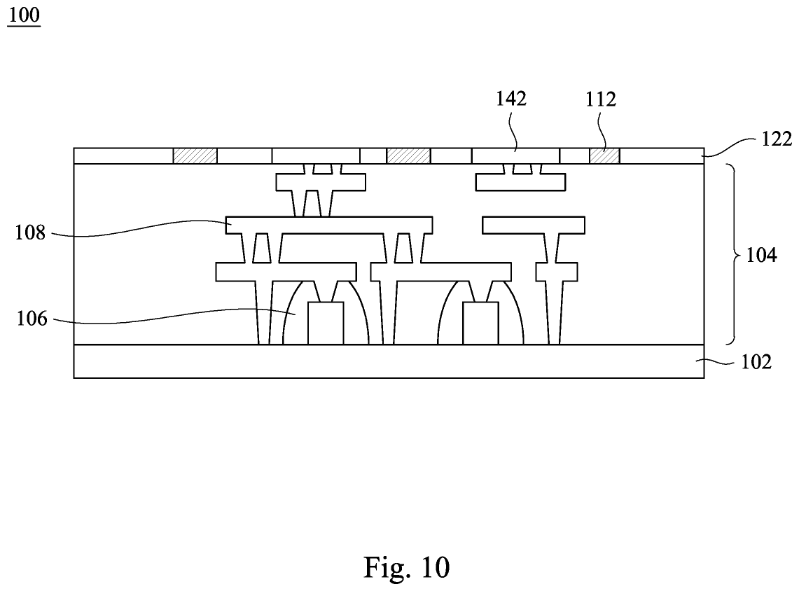

Referring to FIG. 10, a planarization process is performed on the first metal pad 140. In some embodiments, the planarization process is a chemical mechanical planarization (CMP) process. In some embodiments, the planarization process further includes a grinding process. After the planarization process, a top surface of the first magnetic structure 112 is exposed. After the first magnetic structure 112 is exposed, a magnetization process is performed on the first magnetic structure 112. Specifically, a magnetic field is applied to first magnetic structure 112.

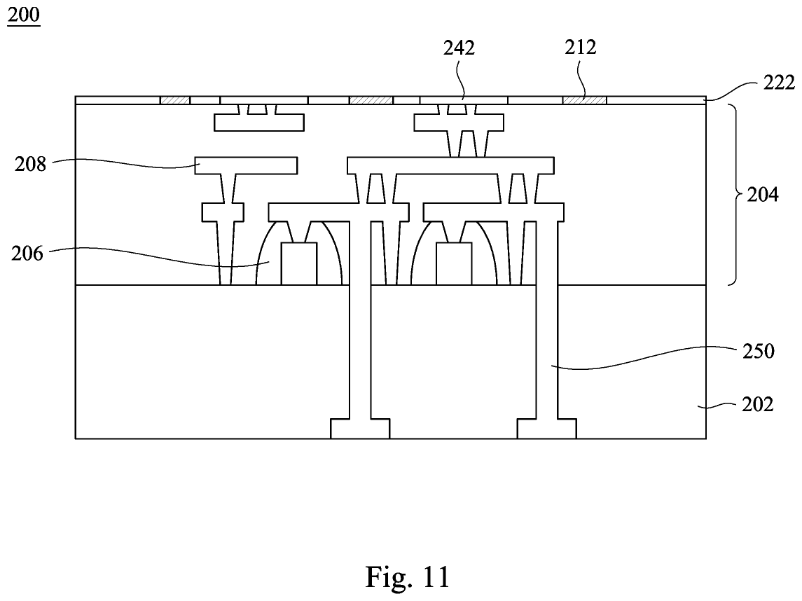

Referring to FIG. 11, a second semiconductor wafer 200 is formed in steps similar to those of FIGS. 1-10. A second substrate 202 and a second metallization layer 204 disposed on a top surface of the second substrate 202 is provided. Then, a second magnetic layer is formed on a top surface of the second metallization layer 204. The second magnetic layer is patterned to form second magnetic structure 212. Next, a second dielectric layer 222 is formed on the second magnetic structure 212, wherein the second magnetic structure 212 is embedded in the second dielectric layer 222. A second metal pad 242 is formed in the second dielectric layer 222. A planarization process is performed to expose a top surface of the second magnetic structure 212; and a magnetization process is performed on the second magnetic structure 212.

The second metallization layer 204 includes transistor 206 and second interconnect structure 208. The second semiconductor wafer 200 includes a conductive via 250 extending form a bottom surface of the second substrate 202 to the second interconnect structure 208 of the second metallization layer 204.

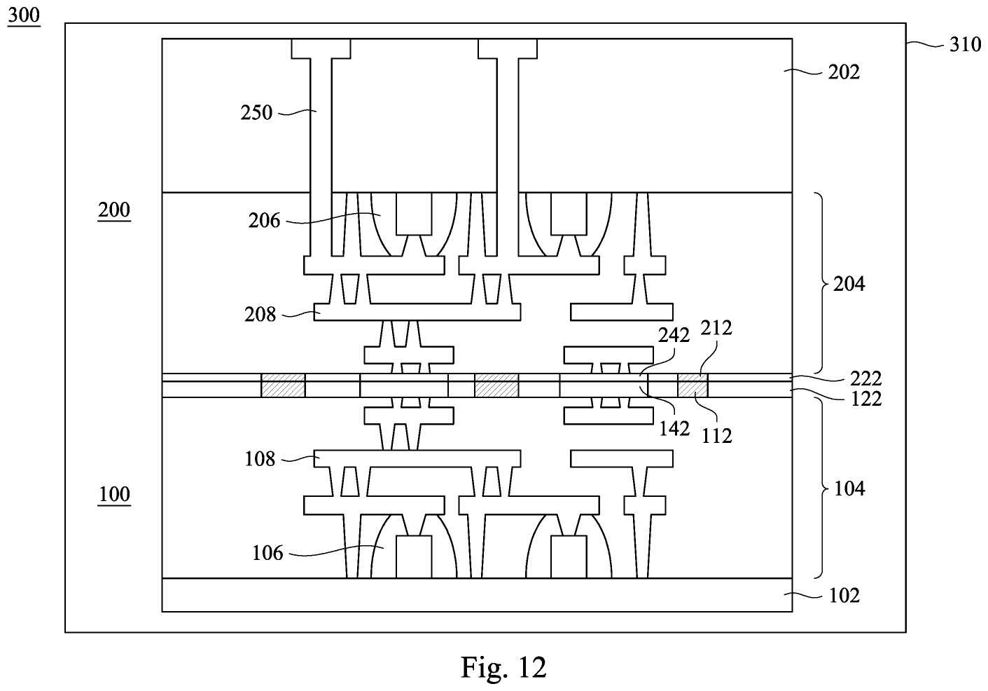

Referring to FIG. 12, the semiconductor device 300 includes the first semiconductor wafer 100 and the second semiconductor wafer 200. The semiconductor device 300 can be applied in an integrated circuit (IC) or a part thereof, such as a logic circuit, a resistor, a capacitor, an inductor, a memory (such as a dynamic random access memory (DRAM)), and the like. It should be understood that some elements of the semiconductor device 300 are not shown in FIG. 12 to simplify the drawings, and that additional elements may be included in other embodiments of the semiconductor device 300. The semiconductor device 300 may include a package structure 310 covering the first semiconductor wafer 100 and the second semiconductor wafer 200.

The first semiconductor wafer 100 and the second semiconductor wafer 200 are bonded by aligning the first magnetic structure 112 and the second magnetic structure 212. The first magnetic structure 112 and the second magnetic structure 212 have opposite polarities. For example, the top surface of the first magnetic structure 112 is north pole and the top surface of the second magnetic structure 212 is south pole. The first magnetic structure 112 and the second magnetic structure 212 direct contact with each other. The top surface of the first metal pad 142 is coplanar with a top surface of the first magnetic structure 112 and a top surface of the second metal pad 242 is coplanar with a top surface of the second magnetic structure 212. The top surface of the first dielectric layer 122 is in direct contact with the top surface of the second dielectric layer 222.

In the present disclosure, the first semiconductor wafer and the second semiconductor wafer are bonded by magnetism force, and are bonded without thermal process and/or pressure process. Therefore, the method provided by the present disclosure can reduce cracks in dielectric film. Also, the method provided by the present disclosure can improve the quality of semiconductor devices.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor device, comprising:
a first semiconductor wafer comprising:
a first substrate;
a first metallization layer disposed on a top surface of the first substrate;
a first dielectric layer disposed on the first metallization layer;
a first magnetic structure embedded in the first dielectric layer; and
a first metal pad embedded in the first dielectric layer, wherein the first metal pad connect with a first interconnect structure in the first metallization layer; and
a second semiconductor wafer disposed on the first semiconductor wafer, wherein the second semiconductor wafer comprises:
a second substrate;
a second metallization layer disposed on a top surface of the second substrate;
a second dielectric layer disposed on the second metallization layer;
a second magnetic structure embedded in the second dielectric layer; and
a second metal pad embedded in the second dielectric layer, wherein the second metal pad connect with a second interconnect structure in the first metallization layer;
wherein the first magnetic structure is aligned with and in direct contact with the second magnetic structure, and a top surface of the first dielectric layer is in direct contact with a top surface of the second dielectric layer.

2. The semiconductor device of claim 1, wherein the first magnetic structure and the second magnetic structure comprise a material selected from the group consisting of iron oxides, iron-cobalt alloy, iron-nickel alloy, iron-aluminum alloy or combinations thereof.

3. The semiconductor device of claim 1, wherein the first magnetic structure and the second magnetic structure have opposite polarities.

4. The semiconductor device of claim 1, further comprising:
a package structure covering the first semiconductor wafer and the second semiconductor wafer.

5. The semiconductor device of claim 1, wherein the second semiconductor wafer comprises a conductive via extending from a bottom surface of the second substrate to the second interconnect structure of the second metallization layer.

6. The semiconductor device of claim 1, wherein a top surface of the first metal pad is coplanar with a top surface of the first magnetic structure and a top surface of the second metal pad is coplanar with a top surface of the second magnetic structure.

7. The semiconductor device of claim 1, wherein the first metal pad is aligned with and in direct contact with the second metal pad.

8. A manufacturing method of a semiconductor device, comprising:
providing a first semiconductor wafer, wherein the first semiconductor wafer comprises a first substrate and a first metallization layer disposed on a top surface of the first substrate;
forming a first magnetic layer on a top surface of the first metallization layer;
patterning the first magnetic layer to form a first magnetic structure;
forming a first dielectric layer on the first magnetic structure, wherein the first magnetic structure is embedded in the first dielectric layer;
forming a first metal pad in the first dielectric layer;
performing a planarization process to expose a top surface of the first magnetic structure; and
performing a magnetization process on the first magnetic structure.

9. The manufacturing method of a semiconductor device of claim 8, wherein patterning the first magnetic layer comprises:
forming a hard mask layer on the first magnetic layer;
forming a photoresist layer on the hard mask layer; and
pattering the photoresist layer and the hard mask layer to define a pattern of the first magnetic structure.

10. The manufacturing method of a semiconductor device of claim 9, further comprising:
stripping the photoresist layer before forming the first dielectric layer on the first magnetic structure.

11. The manufacturing method of a semiconductor device of claim 8, further comprising:
performing a planarization process on the first dielectric layer before forming the first metal pad.

12. The manufacturing method of a semiconductor device of claim 8, wherein forming the first metal pad comprises:
removing a portion of the first dielectric layer to form a trace; and
filling a conductive material in the trace to form the first metal pad.

13. The manufacturing method of a semiconductor device of claim 8, further comprising:
providing a second semiconductor wafer, wherein the second semiconductor wafer comprises a second substrate and a second metallization layer disposed on a top surface of the second substrate;
forming a second magnetic layer on a top surface of the second metallization layer;
patterning the second magnetic layer to form a second magnetic structure;
forming a second dielectric layer on the second magnetic structure, wherein the second magnetic structure is embedded in the second dielectric layer;
forming a second metal pad in the second dielectric layer;
performing a planarization process to expose a top surface of the second magnetic structure; and
performing a magnetization process on the second magnetic structure.

14. The manufacturing method of a semiconductor device of claim 13, wherein the first magnetic structure and the second magnetic structure have opposite polarities.

15. The manufacturing method of a semiconductor device of claim 13, wherein before providing the second semiconductor wafer comprises:
forming a conductive via in the second metallization layer, wherein the conductive via extends from a bottom surface of the second substrate to a interconnect structure of the second metallization layer.

16. The manufacturing method of a semiconductor device of claim 13, further comprising:
aligning the first magnetic structure and the second magnetic structure to bond the first semiconductor wafer and the second semiconductor wafer, wherein the first magnetic structure and the second magnetic structure direct contact with each other.

17. The manufacturing method of a semiconductor device of claim 16, wherein after bonding the first semiconductor wafer and the second semiconductor wafer comprises:
forming a package structure on the second semiconductor wafer, such that the package structure covers the first semiconductor wafer and the second semiconductor wafer.
